(19) United States
(12) Patent Application Publication
(10) Pub. No.: US 2013/0082272 A1
(43) Pub. Date: Apr. 4, 2013

(54) ACTIVE MATRIX SUBSTRATE

(71) Applicants: Isao Nakanishi, Osaka (JP); Satoru Tone, Osaka (JP)

(72) Inventors: Isao Nakanishi, Osaka (JP); Satoru Tone, Osaka (JP)

(73) Assignee: SHARP KABUSHIKI KAISHA, Osaka (JP)

(21) Appl. No.: 13/703,524

(22) PCT Filed: May 9, 2011
(86) PCT No.: PCT/JP2011/002573

§ 371 Date: Dec. 11, 2012

(30) Foreign Application Priority Data
Jun. 15, 2010 (JP) 2010-135808

(51) Int. Cl. H01L 33/00

(52) U.S. Cl. CPC H01L 33/0041
USPC 257/72

(57) ABSTRACT

Disclosed is an active matrix substrate (20a) that is provided with: a plurality of gate lines (14a) that are arranged so as to extend in parallel with each other; a plurality of source lines (16a) that are arranged so as to extend in parallel with each other in a direction that intersects with the respective gate lines (14a); a plurality of TFTs (5a) provided so as to correspond to sections where the gate lines (14a) and source lines (16a) intersect, the plurality of TFTs (5a) being respectively connected to the corresponding gate lines (14a) and source lines (16a); an interlayer insulating film (17) disposed so as to cover the respective TFTs (5a); and a plurality of pixel electrodes (18a) arranged in a matrix on the interlayer insulating film (17). A display region (D) is defined by the plurality of pixel electrodes (18a), and a non-display region (N) is defined in an area around the display region (D). In the non-display region (N), a plurality of conductive layers (18b) that are respectively connected to the gate lines (14a) are provided on the interlayer insulating film (17).

### RELATED ART DOCUMENT

### Patent Document

Patent Document 1: Japanese Patent Application Laid-Open Publication No. H11-271722

### TECHNICAL FIELD

The present invention relates to an active matrix substrate, and more particularly, to a countermeasure against ESD in an active matrix substrate.

### BACKGROUND ART

An active matrix substrate includes a plurality of gate lines disposed so as to extend in parallel with each other, a plurality of source lines disposed so as to extend in parallel with each other in a direction that intersects with the respective gate lines, a plurality of thin film transistors (may also be referred to as “TFTs” below) provided so as to correspond to respective intersections where the respective gate lines intersects with the respective source lines, an interlayer insulating film formed so as to cover the respective TFTs, and a plurality of pixel electrodes that are arranged in a matrix on the interlayer insulating film and that are respectively connected to the respective TFTs, for example. In manufacturing such an active matrix substrate, discharge of static electricity generated during the manufacturing process often causes TFTs and the like to break. Therefore, it is necessary to take a countermeasure against the ESD (electrostatic discharge).

Patent Document 1, for example, discloses an active matrix substrate in which protective circuits are disposed between respective adjacent auxiliary wiring lines that are formed so as to intersect with respective signal lines, which correspond to the respective source lines described above. The protective circuits are provided to protect the substrate from an unwanted high voltage that is applied to the plurality of auxiliary wiring lines.

### SUMMARY OF THE INVENTION

### Problems to be Solved by the Invention

In the active matrix substrate of Patent Document 1 that is provided with the protective circuits, it is possible to suppress the ESD that occurs as a result of the potential difference between the respective adjacent wiring lines. However, in manufacturing the active matrix substrate, after the pixel electrodes are formed, the substrate may undergo a plasma process such as sputtering, dry etching, ashing, or plasma CVD (Chemical Vapor Deposition), causing the surface thereof to be exposed to plasma. In such a case, it is possible that the ESD occurs as a result of the potential difference between the pixel electrodes and the gate lines.

The present invention was made in view of such a problem, and aims at reducing the occurrence of the ESD caused by the potential difference between the pixel electrodes and the gate lines.

### Means for Solving the Problems

In order to achieve the above-mentioned object, in the present invention, a plurality of conductive layers are provided in a non-display region. The plurality of conductive layers are formed on an interlayer insulating film that covers respective thin film transistors, and are respectively connected to gate lines.

Specifically, an active matrix substrate according to the present invention includes: a plurality of gate lines that are disposed so as to extend in parallel with each other; a plurality of source lines that are disposed so as to extend in parallel with each other in a direction intersecting with the respective gate lines; a plurality of thin film transistors provided for respective intersections of the respective gate lines and the respective source lines, the plurality of thin film transistors being respectively connected to the corresponding gate lines and the corresponding source lines; an interlayer insulating film that is disposed so as to cover the respective thin film transistors; and a plurality of pixel electrodes arranged in a matrix on the interlayer insulating film, wherein a display region is defined by the plurality of pixel electrodes, and a non-display region is defined in an area around the display region, respectively, and wherein the active matrix substrate further includes a plurality of conductive layers provided on the interlayer insulating film in the non-display region, the plurality of conductive layers being respectively connected to the respective gate lines.

With this configuration, the plurality of conductive layers are provided in the non-display region. The conductive layers are formed on the interlayer insulating film that covers the respective thin film transistors, and are respectively connected to the respective gate lines. That is, on the interlayer insulating film, i.e., on the surface of the active matrix substrate, the respective pixel electrodes are formed in the display region D, and the respective conductive layers are formed in the non-display region. Therefore, when the surface of the active matrix substrate is exposed to plasma, the respective pixel electrodes and the respective conductive layers have the same potential with respect to the plasma. As a result, the respective pixel electrodes (the drain electrodes of the respective thin film transistors, which are connected to the pixel electrodes) and the respective gate lines that are connected to the respective conductive layers (and the gate electrodes of the respective thin film transistors, which are connected to the respective gate lines) have the same potential, making it possible to suppress the ESD in the respective thin film transistors. Thus, in the respective thin film transistors, the occurrence of the ESD caused by the potential difference between the pixel electrodes and the gate lines can be reduced.

Each of the thin film transistors may include: a source electrode; a drain electrode; and a semiconductor layer, the source electrode being connected to one of the source lines, the drain electrode being connected to one of the pixel electrodes, the semiconductor layer being connected to the source electrode and the drain electrode. In the semiconductor layer, a region thereof on a side of the drain electrode may overlap one of the gate lines.

With this configuration, the region of each semiconductor layer on the side of the drain electrode overlaps one of the gate lines, and by adjusting the overlapping area, a capacitance that is formed between a gate line and the region of the semiconductor layer on the side of the drain electrode can be adjusted in each thin film transistor. This way, the size of the voltage change at the drain electrode relative to the signal voltage that was applied to the source electrode through each source line can be adjusted in each block in the display region. As a result, it is possible to suppress the display non-uniformity caused by the distribution of the optimum potential of the opposite electrode in the in-plane direction. Also, as described above, because the respective gate lines that are connected to the respective conductive layers have the same potential as that of the semiconductor layers of the respective thin film transistors, which are connected to the pixel electrodes through the drain electrodes, in the capacitances formed between the respective gate lines and the regions of the respective semiconductor layers on the side of the drain electrodes of the thin film transistors, it is possible to reduce the occurrence of ESD caused by the potential difference between the pixel electrodes and the gate lines.

Each of the thin film transistors may include a drain electrode that is connected to one of the pixel electrodes, and the drain electrode may overlap one of the gate lines.

With this configuration, each drain electrode overlaps one gate line, and by adjusting the overlapping area, the capacitance formed between the gate line and the drain electrode can be adjusted in each thin film transistor. This way, the size of the voltage change at the drain electrode relative to the signal voltage that was applied to the source electrode through each source line can be adjusted in each block in the display region. As a result, it is possible to suppress the display non-uniformity caused by the distribution of the optimum potential of the opposite electrode in the in-plane direction. Also, as described above, because the respective gate lines connected to the respective conductive layers have the same potential as that of the drain electrodes of the thin film transistors, which are connected to the respective pixel electrodes, in the capacitances formed between the respective gate lines and the drain electrodes of the respective thin film transistors, it is possible to reduce the occurrence of ESD caused by the potential difference between the pixel electrodes and the gate lines.

The respective conductive layers may be made of the same material as that of the respective pixel electrodes.

With this configuration, because the respective conductive layers are formed of the same material as that of the respective pixel electrodes, the respective conductive layers can be formed on the interlayer insulating film without adding a new manufacturing process.

Between each conductive layer and each gate line, a relay layer that is made of the same material as that of the respective source lines and that is formed in the same layer as the respective source lines may be provided.

With this configuration, the relay layers that are formed of the same material as that of the source lines and that are formed in the same layer as the source lines are provided between the respective conductive layers and the respective gate lines. Therefore, a contact hole that connects each conductive layer to a gate line is achieved by relatively shallow holes that are respectively formed in the protective film and in the interlayer insulating film, instead of a relatively deep hole that penetrates the multi-layer film of the protective film and the interlayer insulating film, for example. This makes it easier to form conductive films, which are respectively provided to make the conductive layers and the relay layers, so as to reach the bottom portions of the respective contact holes. As a result, the respective conductive layers can be reliably connected to the respective gate lines.

### Effects of the Invention

According to the present invention, in a non-display region, the plurality of conductive layers that are respectively connected to the respective gate lines are formed on the interlayer insulating film that covers the respective thin film transistors. This makes it possible to reduce the occurrence of ESD caused by a potential difference between the pixel electrodes and the gate lines.

### BRIEF DESCRIPTION OF THE DRAWINGS

FIG. 1 is a plan view of an active matrix substrate according to Embodiment 1.

FIG. 2 is a cross-sectional view of an active matrix substrate along the line II-II in FIG. 1.

FIG. 3 is an equivalent circuit diagram of the active matrix substrate of Embodiment 1.

FIG. 4 is a cross-sectional view of the active matrix substrate of Embodiment 1 during a plasma process.

FIG. 5 is a plan view of an active matrix substrate according to Embodiment 2.

FIG. 6 is a cross-sectional view of an active matrix substrate according to Embodiment 3.

### DETAILED DESCRIPTION OF EMBODIMENTS

Below, embodiments of the present invention will be described in detail with reference to figures. The present invention is not limited to the following embodiments.

### Embodiment 1

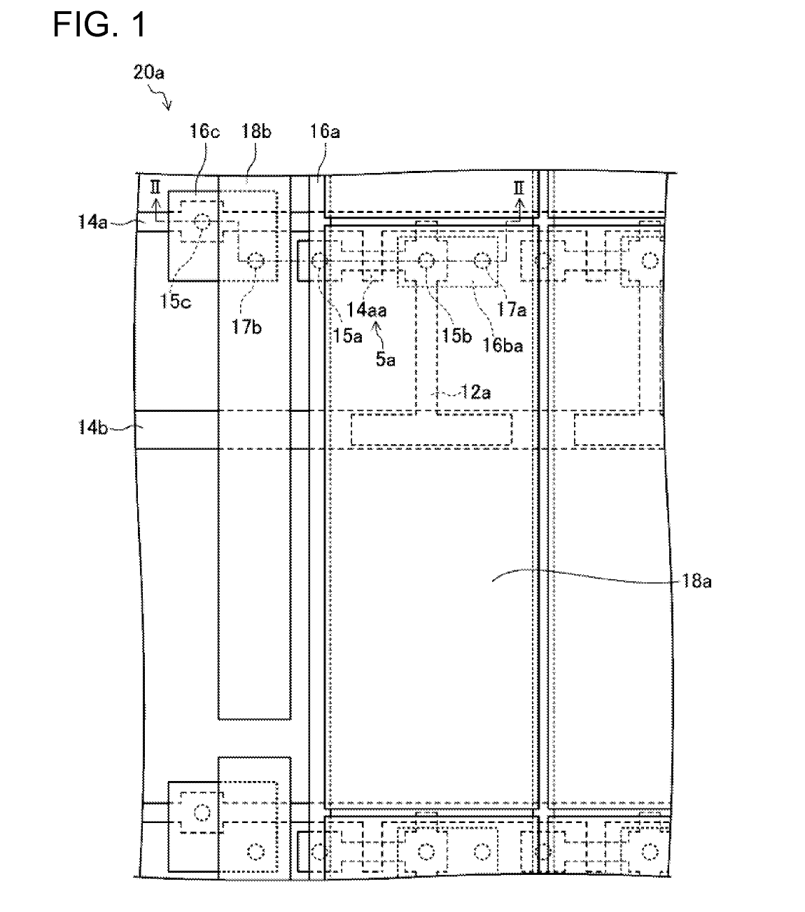

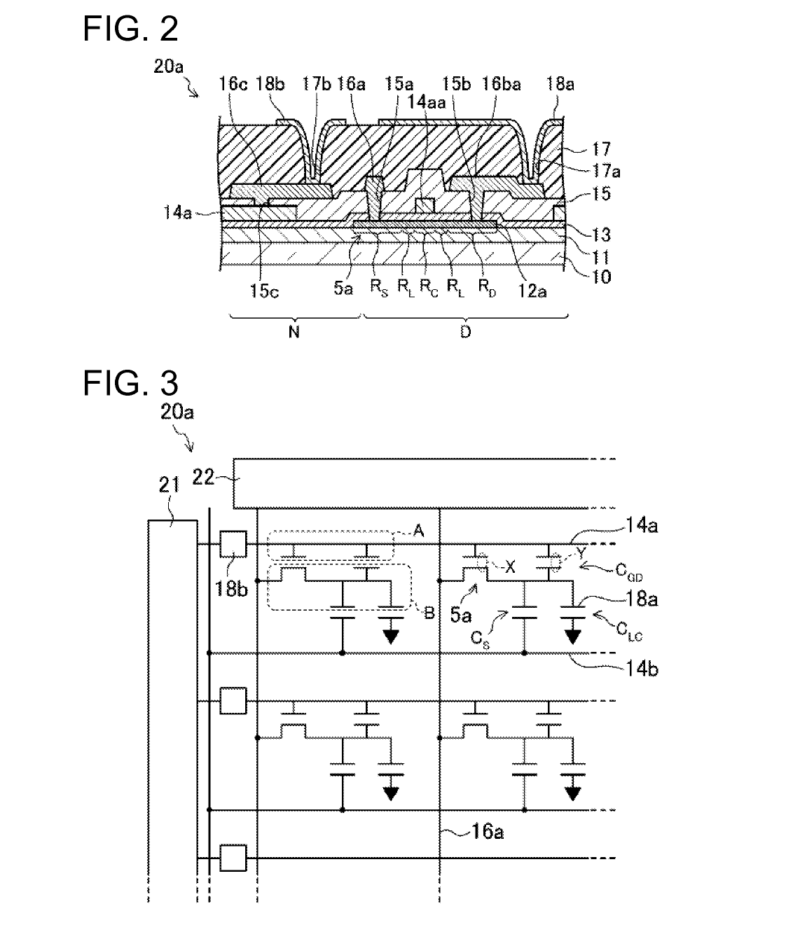

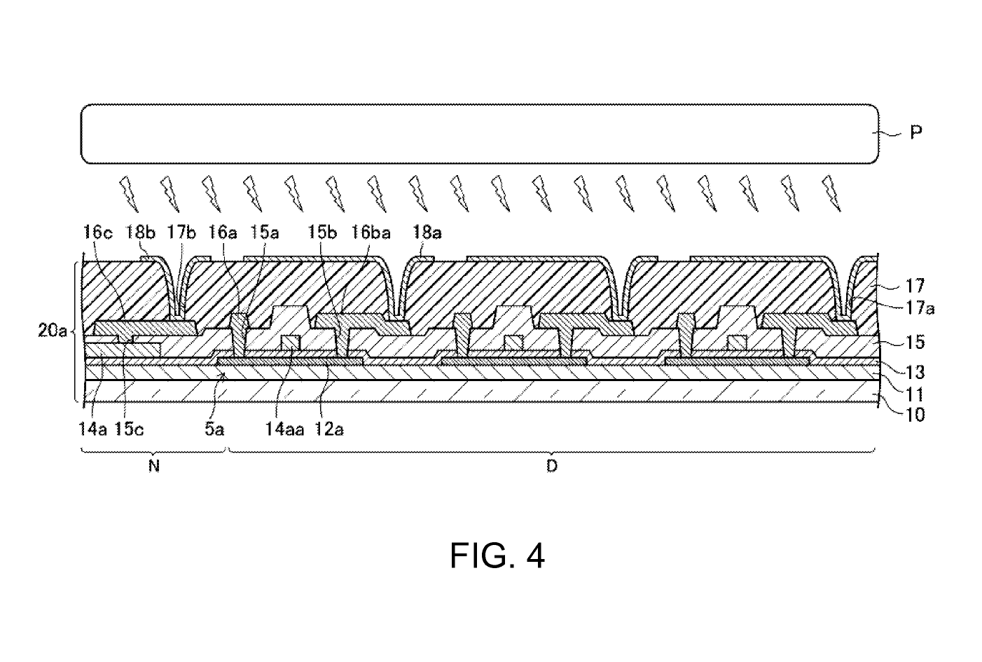

FIGS. 1 to 4 illustrate Embodiment 1 of an active matrix substrate according to the present invention. Specifically, FIG. 1 is a plan view of an active matrix substrate 20a of this embodiment, and FIG. 2 is a cross-sectional view of the active matrix substrate 20a along the line II-II in FIG. 1. FIG. 3 is an equivalent circuit diagram of the active matrix substrate 20a. FIG. 4 is a cross-sectional view of the active matrix substrate 20a during a plasma process.

As shown in FIGS. 1, 2, and 3, the active matrix substrate 20a includes: a plurality of gate lines 14a disposed so as to extend in parallel with each other; a plurality of capacitance lines 14b that are respectively formed between the respective gate lines 14a and that are disposed so as to extend in parallel with each other; a plurality of source lines 16a disposed so as to extend in parallel with each other in a direction orthogonal to the respective gate lines 14a; a plurality of TFTs 5a provided for respective intersections of the respective gate lines 14a and the respective source lines 16a, i.e., for respective pixels; an interlayer insulating film 17 formed so as to cover the respective TFTs 5a; and a plurality of pixel electrodes 18a that are arranged in a matrix on the interlayer insulating film 17. As shown in FIG. 3, the respective gate lines 14a are connected to a gate driver 21 that is mounted on or monolithically formed with the active matrix substrate 20a. Also, as shown in FIG. 3, the respective source lines 16a are connected to a source driver 22 that is mounted on or monolithically formed with the active matrix substrate 20a.

As shown in FIGS. 1 and 2, in the active matrix substrate 20a, a display region D is defined by a plurality of pixel electrodes 18a that are arranged in a matrix, and a non-display region N is defined in an area around the display region D. The display region D is divided into a plurality of blocks that extend in parallel with each other along the respective source lines 16a, and each of the blocks includes a plurality of source lines 16a that are adjacent to each other.

As shown in FIGS. 1, 2, and 3, in the non-display region N of the active matrix substrate 20a, a plurality of conductive layers 18b that are formed on the interlayer insulating film 17 and that are respectively connected to the respective gate lines 14a are provided. As shown in FIGS. 1 and 2, the respective conductive layers 18b are connected to the respective gate lines 14a through relay layers 16c, respectively. That is, as shown in FIGS. 1 and 2, the respective conductive layers 18b are respectively connected to the relay layers 16c through contact holes 17b formed in the interlayer insulating film 17, and as shown in FIGS. 1 and 2, the relay layers 16c are connected to the respective gate lines 14a through contact holes 15c formed in a protective film 15.

As shown in FIGS. 1 and 2, each of the TFTs 5a includes: a semiconductor layer 12a that is formed above an insulating substrate 10 through a base coat film 11; a gate insulating film 13 that is formed so as to cover the semiconductor layer 12a; a gate electrode 14aa formed on the gate insulating film 13 so as to overlap a part (channel region that will be described later) of the semiconductor layer 12a; a protective film 15 formed so as to cover the gate electrode 14aa; and a source electrode (16a) and a drain electrode 16ba that are formed on the protective film 15 so as to be separated from each other.

As shown in FIG. 2, the semiconductor layer 12a includes: a channel region R_{C} formed so as to overlap the gate electrode 14aa; a source region R_{S} and a drain region R_{D} that are formed so as to be apart from each other over the channel region R_{C}; and LDD (Lightly Doped Drain) regions R_{L} that are respectively formed between the channel region R_{C} and the source region R_{S} and between the channel region R_{C} and the drain region R_{D}.

As shown in FIG. 1, the drain region R_{D} (see FIG. 2) of the semiconductor layer 12a overlaps the capacitance line 14b through the gate insulating film (13), thereby forming an auxiliary capacitance (Cs; see FIG. 3). Also, as shown in FIG. 1, the drain region R_{D} (see FIG. 2) of the semiconductor layer 12a also overlaps the gate line 14a through the gate insulating film (13), forming a capacitance (C_{GD}; see FIG. 3). The overlapping area thereof is adjusted in each block in the display region D so as to adjust the size of the voltage change at the drain electrode 16ba relative to a signal voltage that was applied to the source electrode (16a) through each source line 16a. This makes it possible to suppress the display non-uniformity that occurs due to the distribution of the optimum voltage of the opposite electrode in the in-plane direction.

As shown in FIG. 1, the gate electrode 14aa is made of a portion of each gate line 14a that protrudes to the side.

As shown in FIG. 1, each source electrode (16a) is made of a part of a source line 16a, and is thus connected to the source line 16a. Also, as shown in FIGS. 1 and 2, the source electrode (16a) is connected to the source region R_{S} of the semiconductor layer 12a through a contact hole 15a that is formed in a multi-layer film of the protective film 13 and the protective film 15.

As shown in FIGS. 1 and 2, the drain electrode 16ba is connected to the drain region R_{D} of the semiconductor layer 12a through a contact hole 15b formed in a multi-layer film of the protective film 13 and the protective film 15. Also, as shown in FIGS. 1 and 2, the drain electrode 16ba is connected to the pixel electrode 18a through a contact hole 17a formed in the interlayer insulating film 17.

An active matrix driving type liquid crystal display panel is constituted of the active matrix substrate 20a having the above-mentioned configuration, an opposite substrate that is disposed to face the active matrix substrate 20a, and a liquid crystal layer (C_{LC}; see FIG. 3) sealed between the two substrates.

Next, a method of manufacturing the active matrix substrate 20a of this embodiment will be explained.

First, on the insulating substrate 10 such as a glass substrate, a silicon oxide film (about 100 nm thick) or the like is formed by the plasma CVD method, for example, thereby forming a base coat film 11.

Thereafter, on the entire substrate having the base coat film 11 formed thereon, an amorphous silicon film (about 50 nm thick) is formed by the plasma CVD method, for example.

After forming a polysilicon film from the amorphous silicon film by laser annealing, the solid phase epitaxy method, or the like, the polysilicon film is patterned by photolithography, thereby forming a polysilicon layer. In the polysilicon layer, a region that becomes a part of the auxiliary capacitance Cs is doped with an impurity such as phosphorus or boron.

Thereafter, on the entire substrate having the polysilicon layer formed thereon, a silicon oxide film (about 100nm thick) or the like is formed by the plasma CVD method, for example, thereby forming a first inorganic insulating film that becomes the gate insulating film 13.

Next, on the entire substrate having the first inorganic insulating film formed thereon, a tantalum nitride film (about 50 nm thick), a tungsten film (about 350 nm thick), and the like are formed in this order by sputtering, for example. By thereafter patterning the multi-layer film by photolithography, the gate line 14a, the gate electrode 14aa, and the capacitance line 14b are formed.

Next, by using the gate electrode 14aa as a mask, an impurity such as phosphorus or boron is implanted into the polysilicon layer.

Thereafter, a resist is formed over the gate electrode 14aa, and by using the resist as a mask, an impurity such as phosphorus or boron is doped into the polysilicon layer. This impurity doping results in the semiconductor layer 12a that includes: the channel region R_{C} formed in a portion of the polysilicon layer that is covered by the gate electrode 14aa; the LDD regions R_{L} formed in portions on the respective outer sides thereof, which are covered by the resist; and the source region R_{S} and the drain region R_{D} formed in portions on the respective outer sides thereof, which are not covered by the resist. The LDD regions R_{L} have a relatively low impurity concentration, and the source region R_{S} and the drain region R_{D} have a relatively high impurity concentration. If phosphorus was implanted into the polysilicon layer as an impurity, the resultant TFT becomes an n-type polysilicon TFT in which electrons are used as carriers of the channel current. If boron was implanted into the polysilicon layer as an impurity, the resultant TFT becomes a p-type polysilicon TFT in which holes are used as carriers of the channel current.

Further, after the resist is removed, the substrate having the semiconductor layer 12a formed thereon is heated to about 650° C. to 700° C., thereby activating the implanted impurity.

Thereafter, on the entire substrate that has undergone the impurity activation, a silicon oxide film (about 150 nm to 500 nm thick) or the like is formed by the plasma CVD method, for example, thereby forming a second inorganic insulating film that becomes the protective film 15. Then, the multi-layer film of the second inorganic insulating film and the first inorganic insulating film is patterned by photolithography to form contact holes 15a, 15b, and 15c, thereby forming the gate insulating film 13 and the protective film 15.

Next, on the entire substrate having the gate insulating film 13 and the protective film 15 formed thereon, a titanium film (about 100 nm thick), an aluminum film (about 500 nm thick), a titanium film (about 100nm thick), and the like are formed in this order by sputtering, for example. Then, by patterning the multi-layer film by photolithography, the source line 16a, the source electrode (16a), the drain electrode 16ba, and the relay layer 16c are formed.

Next, the substrate having the source line 16a, the source electrode (16a), the drain electrode 16ba, and the relay layer 16c formed thereon is heated to about 400° C. to 500° C. in a hydrogen atmosphere, thereby terminating dangling bonds in the semiconductor layer 12a.

After terminating the dangling bonds in the semiconductor layer 12a, the entire substrate is coated with an acrylic photosensitive resin in a thickness of about 2 μm by a spin coating method or a slit coating method, for example. By patterning the coating film by photolithography, the interlayer insulating film 17 that has contact holes 17a and 17b is formed.

Lastly, on the entire substrate having the interlayer insulating film 17 formed thereon, a transparent conductive film such as an ITO (indium tin oxide) film (about 100 nm thick) is formed by sputtering, for example. Thereafter, the transparent conductive film is patterned by photolithography, thereby forming the pixel electrodes 18a and the conductive layers 18b.

In the manner described above, the active matrix substrate 20a can be manufactured.

Thereafter, if particles are present on the active matrix substrate 20a, a plasma ashing process is performed using plasma P as shown in FIG. 4, thereby removing the particles on the active matrix substrate 20a. At this time, in the active matrix substrate 20a, the potentials at the respective pixel electrodes 18a in the display region D and at the respective conductive layers 18b in the non-display region N are the same with respect to the plasma P. As a result, in each pixel, the portion A and the portion B shown in FIG. 3 have the same potential. This makes it possible to prevent damage in the TFTs 5a (short circuit at the portion X in FIG. 3) and damage in the capacitances C_{GD} (short circuit at the portion Y in FIG. 3) resulting from the ESD.

As described above, according to the active matrix substrate 20a of this embodiment, the plurality of conductive layers 18b are provided in the non-display region N. The conductive layers 18b are formed on the interlayer insulating film 17 that covers the respective TFTs 5a, and are respectively connected to the respective gate lines 14a. Therefore, on the interlayer insulating film 17, that is, on the surface of the active matrix substrate 20a, the pixel electrodes 18a are formed in the display region D, and the conductive layers 18b are formed in the non-display region N. With this configuration, when the surface of the active matrix substrate 20a is exposed to plasma in ashing, the respective pixel electrodes 18a and the respective conductive layers 18b have the same potential with respect to the plasma P. As a result, the drain electrodes 16ba of the respective TFTs 5a, which are connected to the respective pixel electrodes 18a, and the respective gate lines 14a that are connected to the respective conductive layers 18b and the gate electrodes 14aa of the respective TFTs 5a, which are connected to the gate lines 14a, have the same potential, making it possible to suppress the ESD in the respective TFTs 5a. Thus, in the respective TFTs 5a, the occurrence of ESD that is caused by the potential difference between the pixel electrodes 18a and the gate lines 14a can be reduced.

According to the active matrix substrate 20a of this embodiment, the drain region R_{D} of each semiconductor layer 12a overlaps the gate line 14a, and by adjusting the overlapping area, the capacitance C_{GD} formed between the gate line 14a and the drain region R_{D} of the semiconductor layer 12a can be adjusted for each TFT 5a. This way, the size of the voltage change at the drain electrodes 16ba relative to the signal voltage that was applied to the source electrodes (16a) through the respective source lines 16a can be adjusted in each block in the display region D. As a result, it becomes possible to suppress the display non-uniformity caused by the distribution of the optimum potential at the opposite electrode in the in-plane direction. Also, because the respective gate lines 14a connected to the respective conductive layers 18b have the same potential as that of the semiconductor layers 12a connected to the respective pixel electrodes 18a through the drain electrodes 16ba of the TFTs 5a, in the capacitances C_{GS} that is formed between the respective gate lines 14a and the drain regions R_{D} of the semiconductor layers 12a of the respective TFTs 5a, it is possible to reduce the occurrence of ESD caused by the potential difference between the pixel electrodes 18a and the gate lines 14a.

According to the active matrix substrate 20a of this embodiment, the respective conductive layers 18b are formed of the same material as that of the respective pixel electrodes 18a. This makes it possible to form the respective conductive layers 18b on the interlayer insulating film 17 without adding a new manufacturing process.

According to the active matrix substrate 20a of this embodiment, the relay layers 18c that are formed of the same material as that of the source lines 18a and that are formed in the same layer as the source lines are respectively provided between the conductive layers 18b and the gate lines 14a. Therefore, a contact hole that connects each conductive layer 18b to a gate line 14a is achieved by relatively shallow holes that are respectively formed in the protective film 15 and in the interlayer insulating film 17 (contact holes 15c and 17b), instead of a relatively deep hole that penetrates the multi-layer film of the protective film and the interlayer insulating film, for example. This makes it easier to form conductive films, which are respectively provided to make the conductive layers 18b and the relay layers 16c, so as to reach the bottom portions of the respective contact holes 15c and 17b. As a result, the respective conductive layers 18b can be reliably connected to the respective gate lines 14a.

### Embodiment 2

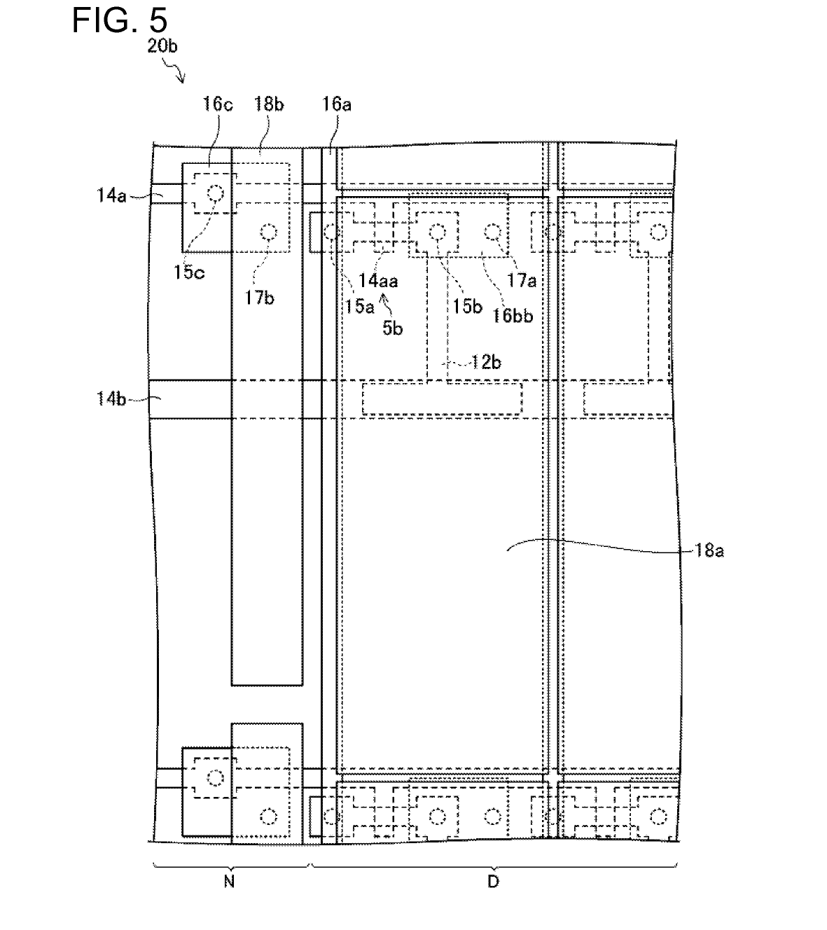

FIG. 5 is a plan view of an active matrix substrate 20b of Embodiment 2. In the respective embodiments below, the same portions as those in FIGS. 1 to 4 are given the same reference characters, and the detailed descriptions thereof are omitted.

In Embodiment 1 above, the active matrix substrate 20a in which a part of the drain region R_{D} in each semiconductor layer 12a overlaps a gate line 14a was described as an example. However, in this embodiment, an active matrix substrate 20b in which each drain electrode 16bb overlaps a gate line 14a will be described as an example.

Specifically, in the active matrix substrate 20b, as shown in FIG. 5, a plurality of TFTs 5b are provided so as to respectively correspond to the intersections of the respective gate lines 14a and the respective source lines 16a.

As shown in FIG. 5, each TFT 5b includes: a semiconductor layer 12b disposed above an insulating substrate (10) through a base coat film (11); a gate insulating film 13 disposed so as to cover the semiconductor layer 12b; a gate electrode 14aa disposed on the gate insulating film (13) so as to overlap a part of the semiconductor layer 12b; a protective film (15) disposed so as to cover the gate electrode 14aa; and a source electrode (16a) and a drain electrode 16bb disposed so as to be separated from each other on the protective film (15).

In a manner similar to the semiconductor layer 12a of Embodiment 1, the semiconductor layer 12b includes: the channel region (R_{C}) disposed so as to overlap the gate electrode 14aa; the source region (R_{S}) and the drain region (R_{D}) disposed so as to be apart from each other over the channel region (R_{C}); and LDD regions (R_{L}) respectively formed between the channel region (R_{C}) and the source region (R_{S}) and between the channel region (R_{C}) and the drain region (R_{D}).

As shown in FIG. 5, the drain region (R_{D}) of the semiconductor layer 12b overlaps the capacitance line 14b through the gate insulating film (13), thereby forming the auxiliary capacitance (Cs; see FIG. 3). It should be noted that, unlike the semiconductor layer 12a of Embodiment 1 above, the drain region (R_{D}) of the semiconductor layer 12b is formed so as not to overlap the gate line 14a as shown in FIG. 5.

As shown in FIG. 5, the source electrode (16a) is connected to the source region (R_{S}) of the semiconductor layer 12b through the contact hole 15a formed in the multi-layer film of the protective film (13) and the interlayer insulating film (15).

As shown in FIG. 5, the drain electrode 16bb is connected to the drain region (R_{D}) of the semiconductor layer 12b through the contact hole 15b that is formed in the multi-layer film of the protective film (13) and the interlayer insulating film (15). Also, as shown in FIG. 5, the drain electrode 16bb is connected to the pixel electrode 18a through the contact hole 17a that is formed in the interlayer insulating film (17). Further, as shown in FIG. 5, the drain electrode 16bb overlaps the gate line 14a through the gate insulating film (13) and the protective film (15), thereby forming a capacitance (C_{GD}; see FIG. 3). The overlapping area thereof is adjusted in each block in the display region D so as to adjust the size of the voltage change at the drain electrode 16bb relative to a signal voltage that was applied to the source electrode (16a) through each source line 16a. This makes it possible to suppress the display non-uniformity that occurs due to the distribution of the optimum potential at the opposite electrode in the in-plane direction.

The active matrix substrate 20b having the above-mentioned configuration can be manufactured by modifying the pattern shapes of the semiconductor layers 12a and the drain electrodes 16ba in the manufacturing method of Embodiment 1 above.

As described above, according to the active matrix substrate 20b of this embodiment, in a manner similar to Embodiment 1 above, the plurality of conductive layers 18b are provided in the non-display region N. The conductive layers 18b are formed on the interlayer insulating film 17 that covers the respective TFTs 5b, and are respectively connected to the respective gate lines 14a. Thus, in the respective TFTs 5b, the occurrence of ESD caused by the potential difference between the pixel electrodes 18a and the gate lines 14a can be reduced.

According to the active matrix substrate 20b of this embodiment, each drain electrode 16bb overlaps a gate line 14a, and by adjusting the overlapping area, the capacitance C_{GD} that is formed between the gate line 14a and the drain electrode 16bb can be adjusted for each TFT 5b. This way, the size of the voltage change at the drain electrode 16bb relative to the signal voltage that was inputted to the source electrode (16a) through each source line 16a can be adjusted in each block in the display region D. As a result, it becomes possible to suppress the display non-uniformity caused by the distribution of the optimum potential at the opposite electrode in the in-plane direction. Also, because the respective gate lines 14a connected to the respective conductive layers 18b have the same potential as that of the drain electrodes 16bb of the respective TFTs 5b connected to the respective pixel electrodes 18a, in the capacitances C_{GD} formed between the respective gate lines 14a and the drain electrodes 16bb of the respective TFTs 5b, it is possible to reduce the occurrence of ESD caused by the potential difference between the pixel electrodes 18a and the gate lines 14a.

### Embodiment 3

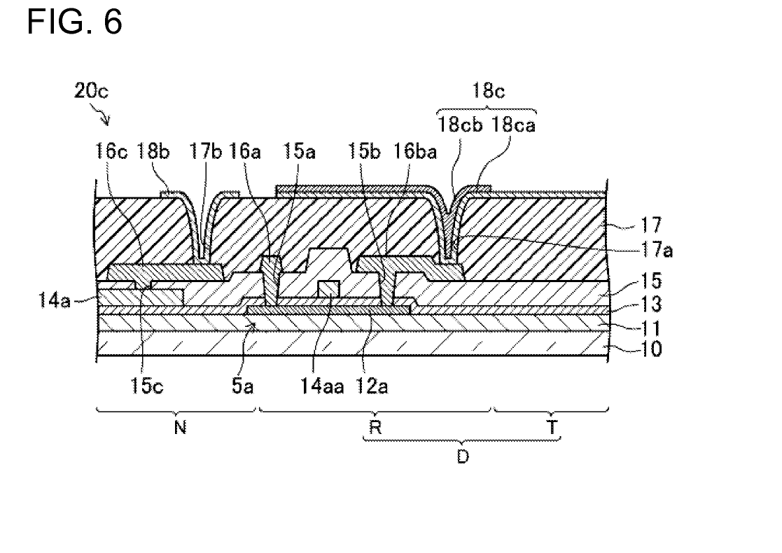

FIG. 6 is a cross-sectional view of an active matrix substrate 20c of Embodiment 3.

In the respective embodiments above, the active matrix substrates 20a and 20b for a transmissive liquid crystal display panel were described as examples. However, in this embodiment, an active matrix substrate 20c for a transflective liquid crystal display panel will be described as an example.

As shown in FIG. 6, in the active matrix substrate 20c, each pixel electrode 18c is constituted of a transparent electrode 18ca that corresponds to the pixel electrode 18a in the active matrix substrate 20a of Embodiment 1 and a reflective electrode 18cb that is disposed on a part of the transparent electrode 18ca. Other configurations are substantially the same as those of the active matrix substrate 20a. In each pixel of the active matrix substrate 20c, the reflective electrode 18cb is formed so as to cover a region where the TFT 5a is disposed between the gate line 14a and the capacitance line 14b, for example, which forms a reflective region R. A region between the gate line 14a and the capacitance line 14b where the TFT 5a is not formed and where the transparent electrode 18ca is exposed from the reflective electrode 18cb is a transmissive region T. In this embodiment, the active matrix substrate 20c has an exemplary configuration in which each reflective electrode 18cb is formed so as to cover the region where a TFT 5a is disposed between the gate line 14a and the capacitance line 14b. However, the reflective electrodes may be formed in other regions.

The active matrix substrate 20c having the above-mentioned configuration can be manufactured as follows: the transparent electrodes 18ca and the conductive layers 18b are formed on the interlayer insulating film 17 by conducting the method of manufacturing the active matrix substrate 20a of Embodiment 1 above; a molybdenum film (about 75 nm thick) and an aluminum film (about 100 nm thick) are formed in this order by sputtering, for example, on the entire substrate where the transparent electrodes 18ca and the conductive layers 18b are formed; and the multi-layer film is patterned by photolithography, thereby forming the reflective electrodes 18cb.

As described above, according to the active matrix substrate 20c of this embodiment, in a manner similar to the respective embodiments above, the plurality of conductive layers 18b are provided in the non-display region N. The conductive layers 18b are formed on the interlayer insulating film 17 that covers the respective TFTs 5a, and are respectively connected to the respective gate lines 14a. Therefore, on the interlayer insulating film 17, that is, on the surface of the active matrix substrate 20c, the respective pixel electrodes 18c are formed in the display region D, and the respective conductive layers 18b are formed in the non-display region N. With this configuration, when the surface of the active matrix substrate 20c is exposed to plasma in ashing, which is performed to remove the particles on the surface of the active matrix substrate 20c, for example, the respective pixel electrodes 18c and the respective conductive layers 18b have the same potential with respect to the plasma P. As a result, the drain electrodes 16ba of the respective TFTs 5a, which are connected to the respective pixel electrodes 18c, have the same potential as that of the respective gate lines 14a that are connected to the respective conductive layers 18b and the gate electrodes 14aa of the respective TFTs 5a, which are connected to the respective gate lines 14a, making it possible to suppress the ESD in the respective TFTs 5a. Thus, in the respective TFTs 5a, the occurrence of ESD caused by the potential difference between the pixel electrodes 18c and the gate lines 14a can be reduced.

Also, according to the active matrix substrate 20c of this embodiment, in a process of forming a conductive film that is used to make the reflective electrodes, in the non-display region N, the plurality of conductive layers 18b have been formed. The conductive layers 18b are formed on the interlayer insulating film 17 that covers the respective TFTs 5a, and are respectively connected to the respective gate lines 14a. That is, on the interlayer insulating film 17, the respective transparent electrodes 18ca are formed in the display region D, and the respective conductive layers 18b are formed in the non-display region N. With this configuration, when the surface of the substrate is exposed to plasma in sputtering, the respective transparent electrodes 18ca and the respective conductive layers 18b have the same potential with respect to the plasma P. As a result, the drain electrodes 16ba of the respective TFTs 5a, which are connected to the respective transparent electrodes 18ca, have the same potential as that of the respective gate lines 14a that are connected to the respective conductive layers 18b and the gate electrodes 14aa of the respective TFTs 5a, which are connected to the respective gate lines 14a, making it possible to suppress the ESD in the respective TFTs 5a. Thus, in the respective TFTs 5a, the occurrence of ESD caused by the potential difference between the transparent electrodes 18ca and the gate lines 14a can be reduced.

In this embodiment, the active matrix substrate 20c that is obtained by applying the transflective technology to the active matrix substrate 20a of Embodiment 1 was described as an example, but the transflective technology can also be applied to the active matrix substrate 20b of Embodiment 2.

In each of the embodiments above, the active matrix substrate having top-gate TFTs was described as an example, but the present invention can also be applied to an active matrix substrate having bottom-gate TFTs.

In each of the embodiments above, the active matrix substrate in which the conductive layers on the interlayer insulating film are formed of the same material as that of the pixel electrodes was described as an example, but the conductive layers may be formed of another conductive film.

In each of the embodiments above, the active matrix substrate that can reduce the occurrence of ESD caused by a potential difference between the pixel electrodes and the gate lines was described as an example. However, the active matrix substrate may also be configured so as to suppress ESD that occurs as a result of a potential difference between respective adjacent wiring lines, by providing protective circuits between the respective adjacent wiring lines such as the gate lines or the source lines, for example.

In each of the embodiments above, the active matrix substrate in which the drain electrodes of the TFTs are connected to the pixel electrodes was described as an example, but the present invention can also be applied to an active matrix substrate in which pixel electrodes are connected to the source electrodes of respective TFTs.

### INDUSTRIAL APPLICABILITY

As described above, the present invention makes it possible to reduce the occurrence of ESD caused by a potential difference between the pixel electrodes and the gate lines. Therefore, the present invention is useful for an active matrix substrate included in a display panel such as a liquid crystal display panel or an organic EL (Electroluminescence) panel.

### DESCRIPTIONS OF REFERENCE CHARACTERS

D display region

N non-display region

5a, 5b TFT

12a, 12b semiconductor layer

14a gate line

16a source line (source electrode)

16ba, 16bb drain electrode

16c relay layer

17 interlayer insulating film

18a, 18c pixel electrode

18b conductive layer

20a, 20b, 20c active matrix substrate

1. An active matrix substrate, comprising:
a plurality of gate lines that are disposed so as to extend in parallel with each other;
a plurality of source lines that are disposed so as to extend in parallel with each other in a direction intersecting with the respective gate lines;
a plurality of thin film transistors provided so as to respectively correspond to intersections of the respective gate lines and the respective source lines, the plurality of thin film transistors being respectively connected to the corresponding gate lines and the corresponding source lines;
an interlayer insulating film that is disposed so as to cover the respective thin film transistors; and
a plurality of pixel electrodes arranged in a matrix on the interlayer insulating film,
wherein a display region is defined by the plurality of pixel electrodes, and a non-display region is defined in an area around the display region, respectively, and
wherein the active matrix substrate further comprises a plurality of conductive layers provided on the interlayer insulating film in the non-display region, the plurality of conductive layers being respectively connected to the respective gate lines.

2. The active matrix substrate according to claim 1,
wherein each of the thin film transistors comprises: a source electrode; a drain electrode; and a semiconductor layer, the source electrode being connected to one of the source lines, the drain electrode being connected to one of the pixel electrodes, the semiconductor layer being connected to the source electrode and the drain electrode, and
wherein a region of the semiconductor layer on a side of the drain electrode overlaps one of the gate lines.

3. The active matrix substrate according to claim 1,
wherein each of the thin film transistors comprises: a drain electrode that is connected to one of the pixel electrodes, and
wherein the drain electrode overlaps one of the gate lines.

4. The active matrix substrate according to claim 1,
wherein the respective conductive layers are made of a same material as that of the respective pixel electrodes.

5. The active matrix substrate according to claim 1, further comprising a relay layer between each of the conductive layers and each of the gate lines, the relay layer being made of a same material as that of the respective source lines and being formed in a same layer as the respective source lines.
